(19) United States
(12) Patent Application Publication
(10) Pub. No.: US 2026/0339146 A1
(43) Pub. Date: Oct. 29, 2026

(54) DIGITAL DISPLAY SCREEN AND VEHICLE COMPONENT COMPRISING SUCH A DIGITAL DISPLAY SCREEN

(71) Applicant: Faurecia Clarion Electronics Europe, Paris (FR)

(72) Inventors: Edouard DA SILVA, PONTOISE (FR); Romain FEILLEUX, EPINAY SUR SEINE (FR); Tara AKHAVAN, Montreal (CA); Hyunjin YOO, Montreal (CA); James GOURLAY, DUMBARTON (GB); Nizar TARABAY, Montreal (CA)

(21) Appl. No.: 19/635,612

(22) Filed: Mar. 31, 2026

(30) Foreign Application Priority Data
Mar. 31, 2025 (FR) FR 25 03305

(51) Int. Cl. G02F 1/1335; B60K 35/22; G02F 1/1333; G02F 1/13357; H10D 86/40

(52) U.S. Cl. CPC G02F 1/133524; B60K 35/22; G02F 1/133308; G02F 1/133504; G02F 1/133526; G02F 1/133603; H10D 86/40

(57) ABSTRACT

The invention concerns a digital display screen (10) comprising: a back cover layer (12), a displaying layer (14) comprising an image displaying element (18), and a backlighting device (16) configured to backlight said displaying layer (14), the backlighting device (16) being arranged between the back cover layer (12) and the displaying layer (14) according to a main direction (X), the backlighting device (16) comprising a light-guiding layer (24) defining a first zone (24-1) and at least one second zone (24-2) according to a second direction (Y) perpendicular to the main direction (X). The backlighting device (16) comprises a plurality of lighting sources (26) arranged inside the first zone (24-1), the backlighting device (16) comprising at least one optical film (32) arranged inside each second zone (24-2).

### TECHNICAL FIELD

The present invention relates to the technical field of digital display screens, in particular to digital display screens comprising an image display element, such as a liquid- crystal display (LCD), configured to generate an image, and a backlighting unit configured for backlighting the image display element.

### BACKGROUND

A digital display screen can be used in a vehicle to display different types of images to the user.

However, display screens with a large surface are expensive, notably due to the large number of light emitting diodes (LEDs) that are necessary for backlighting the image display element.

In addition, the large number of LEDs required results in high power consumption.

### SUMMARY

One of the aims of the invention is to propose a large digital display screen that has satisfactory performances whilst being cost and energy saving.

To this end, the invention proposes a digital display screen comprising:
a back cover layer,
a displaying layer comprising an image displaying element, and
a backlighting device configured to backlight said displaying layer, the backlighting device being arranged between the back cover layer and the displaying layer according to a main direction, the backlighting device comprising a light-guiding layer defining a first zone and at least one second zone according to a second direction perpendicular to the main direction.

The backlighting device comprises a plurality of lighting sources arranged inside the first zone of the light-guiding layer, the backlighting device comprising at least one optical film arranged inside each of the at least one second zone of the light-guiding layer.

In this digital display screen, only the first zone of the backlighting device comprises lighting sources. The areas in regards of the second zone(s) of the backlighting device are indirectly backlighted thanks to the light-guiding layer transmitting the light generated by the lighting sources of the first zone.

This allows reducing the number of lighting sources, and thus reducing the cost and saving energy.

In specific embodiments, the digital display screen comprises one or several of the following features, taken individually or in any technically feasible combination:

The light-guiding layer defines two second zones, the first zone being arranged between the two second zones according to the second direction.

The digital display screen comprises a cover lens covering the displaying layer.

The image displaying element is a thin-film-transistor liquid-crystal display.

The displaying layer comprises a decorative layer facing the first zone of the backlighting device.

The displaying layer comprises a diffusing layer arranged between the decorative layer and the first zone of the backlighting device.

The backlighting device comprises a plurality of barriers arranged inside the first zone of the light-guiding layer, each barrier being arranged longitudinally between each two of the plurality of lighting sources.

Each of the plurality of lighting sources is a light emitting diode.

The invention further relates to a vehicle component comprising at least one digital display screen as described above.

### BRIEF DESCRIPTION OF THE DRAWINGS

The invention and its advantages will be better understood upon reading the following description given solely by way of non-limiting examples and made with reference to the appended drawings in which:

FIG. 1 is a cross-sectional view of a digital display screen according to a first embodiment of the invention; and

FIG. 2 is a cross-sectional view of a digital display screen according to a second embodiment of the invention.

### DETAILED DESCRIPTION

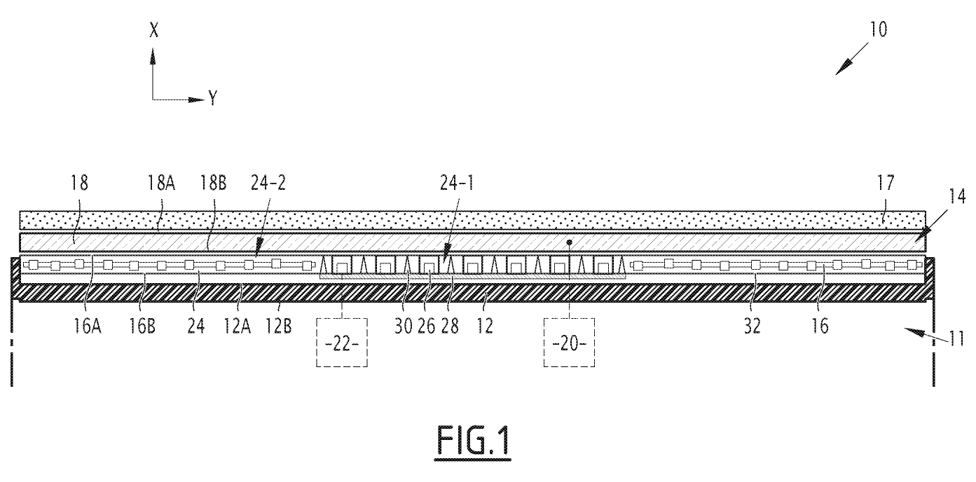

FIG. 1 shows a digital display screen 10 according to a first embodiment of the invention.

The digital display screen 10 comprises a back cover layer 12, a displaying layer 14, a backlighting device 16 and preferably also a cover lens 17.

In a preferred manner, in the digital display screen 10, the back cover layer 12, the displaying layer 14, the backlighting device 16 and the cover lens 17 are superimposed one on top of the other, preferably in that order, along a main direction X.

In a particular embodiment, the displaying layer 14 is optically bonded to the covers lens 17, in order to remove unwanted reflections. The other layers are for example mechanically fastened at the edges of a component 11.

The digital display screen 10 is preferably integrated in a component 11, in particular a component 11 of a vehicle, for example an automotive vehicle.

The component 11 is for example a vehicle interior trim, e.g. a dashboard, a door panel or a ceiling.

The back cover layer 12 defines preferably the support of the digital display screen 10.

In particular, the back cover layer 12 has for example a front surface 12A and a rear surface 12B opposite to each other according to the main direction X.

The front surface 12A is preferably oriented towards the interior of the vehicle cabin.

The rear surface 12B is for example fixed to the component 11, for example glued to an outer face of the component 11.

Alternatively, the back cover layer 12 is part of the component 11. The front surface 12A is defined by the outer face of the component 11

The displaying layer 14 comprises an image-displaying element 18.

In the first embodiment shown on the FIG. 1, the displaying layer 14 consists of said image-displaying element 18.

The image-displaying element 18 is preferably an optical device configured to generate image to be displayed to the user.

Preferably, the image-displaying element 18 is a liquid-crystal display (LCD), in particular a thin-film-transistor (TFT) liquid-crystal display.

The image-displaying element 18 has a front surface 18A and a rear surface 18B. The front surface 18A is intended to be visible by the user.

The image-displaying element 18 is for example plate shaped, the front surface 18A and the rear surface 18B being the two opposed faces of the image-displaying element 18 according to the main direction X.

Preferably, the digital display screen 10 comprises a display control unit 20 to control the generation of the image displayed by the image-displaying element 18.

The backlighting device 16 is configured to backlight said displaying layer 14, and in particular said image displaying element 18.

More particularly, the backlighting device 16 is arranged to backlight the rear surface 18B of the image-displaying element 18 such that the image is visible on the front surface 18A of the image-displaying element 18.

Preferably, the digital display screen 10 comprises a lighting control unit 22 to control the lighting generated by the backlighting device 16, and in particular the lighting intensity.

As visible on FIG. 1, the backlighting device 16 is arranged between the back cover layer 12 and the displaying layer 18 according to the main direction X.

More precisely, the backlighting device 16 has a front surface 16A and a rear surface 16B. The front surface 16A is preferably facing the rear surface 18B of the image-displaying element 18. The rear surface 16B is preferably facing the front surface 12A of the back cover layer 12.

The backlighting device 16 is for example plate shaped, the front surface 16A and the rear surface 16B being the two opposed faces according to the main direction X.

The backlighting device 16 comprises a light-guiding layer 24.

As visible on FIG. 1, the light-guiding layer 24 is preferably plate shaped and extends between the front surface 16A and the rear surface 16B of the backlighting device 16.

Preferably, the light-guiding layer 24 is made in a light transmitting material and provides an optical function of distributing light inside said layer 24.

For example, the light-guiding layer 24 is made of a transparent polymer, such as silicone, polyurethane, epoxy, polycarbonate or acrylic/PMMA (Poly(methyl methacrylate).

The light-guiding layer 24 defines a first zone 24-1 and at least one second zone 24-2 according to a second direction Y perpendicular to the main direction X.

In the example shown on the FIG. 1, the light-guiding layer 24 defines one first zone 24-1 and two second zones 24-2.

More precisely, the first zone 24-1 is arranged according to the second direction Y between the two second zones 24-2.

In other words, the first zone 24-1 is a central zone, while the two second zones 24-2 are outer zones.

In the particular embodiment example shown on the FIG. 1, the light-guiding layer 24 faces entirely the image-displaying element 18, i.e. the first zone 24-1 and the second zones 24-2 face the image-displaying element 18.

As will be explained below, the first zone 24-1 is for example configured to a direct backlighting of the displaying layer 14, and in particular of the image displaying element 18. The second zone(s) 24-2 are for example configured to an indirect backlighting of the displaying layer 14, and in particular of the image-displaying element 18.

The backlighting device 16 comprises a plurality of lighting sources 26 arranged inside the first zone 24-1 of the light-guiding layer 24.

Preferably, the lighting sources 26 are only arranged inside the first zone 24-1 of the light-guiding layer 24.

In other words, no lighting source 26 is arranged inside the second zone(s) 24-2 of the light-guiding layer 24.

In some examples, the lighting sources 26 are covered by and/or embedded in the light-guiding layer 24, and in particular in the first zone 24-1.

The lighting sources 26 covered by and/or embedded in the light-guiding layer 24 are preferably not exposed to surrounding atmosphere.

In one example, the backlighting device 16 comprises a base layer 28, for example, a printed circuit board (PCB), onto which the lighting sources 26 are secured; the light guiding layer 24, and in particular the first zone 24-1, covering the base layer 28.

Said base layer 28 is for example made in a polymeric plastic such as polycarbonate or PET, for example, said base layer 28 is a flexible PCB. .

More precisely, the lighting sources 26 are configured for emitting light in direction to the displaying layer 14, in particular in order to direct backlighting the displaying layer 14, and in particular the image displaying element 18.

In a preferred embodiment, the lighting sources 26 are light emitting diodes (LED).

The lighting sources 26 are for example controllable by the lighting control unit 22.

In particular, the lighting control unit 22 is able to control individually each lighting source 26, for example to dim it.

The lighting control unit 22 is for example disposed on said base layer 28.

In a preferred embodiment, the backlighting device 16 comprises a plurality of barriers 30 arranged inside the first zone 24-1 of the light-guiding layer 24.

For example, each barrier 30 is arranged longitudinally between two light sources 26.

More particularly, each barrier 30 laterally separates light from each lighting source 26 from its surrounding light sources 26, for example its nearest 9 neighbours.

Preferably, each barrier 30 is configured for blocking at least part of the light hitting said barrier 30, in order to allow only a controlled amount of light to be transmitted, in particular into the zone of the 9 surrounding lighting sources.

Generally, each barrier 30 has a transmittance of light from one zone to another, between 0% to 100%, so enabling a wide range of Point Spread Functions to be designed into the local dimming system. In one example, 50% of the light from each lighting source 26 in each zone is transmitted into the zone of the 9 surrounding lighting sources.

In one example, each barrier 30 has a cross-section of substantially triangular shape or parabolic shape.

In other word, the width of the cross-section of each barrier 30 becomes gradually narrower near the front surface of the light-guiding layer 24.

The barriers 30 are preferably covered and/or embedded in the light-guiding layer 24.For example, as shown on FIG. 1, the barrier 30 are secured on the base layer 28.

In one example, each light source 26 has a feature above it on the light-guiding layer 24 configured to reduce any brighter “hot spot”.

The backlighting device 16 comprises at least one optical film 32 arranged inside the or each second zone 24-2 of the light-guiding layer 24.

Preferably, the optical film(s) 32 are only arranged inside the second zone(s) 24-2 of the light-guiding layer 24.

In other words, no optical film 32 is arranged inside the first zone 24-1 of the light-guiding layer 24.

Preferably, the optical film 32 confers specific optical features to the corresponding second zone 24-2 of the light-guiding layer 24

The optical film 32 is for example a diffuser, in particular having a distribution of light scattering features, which ensure an even distribution of light exiting from the light-guiding layer across the surface.

In another example, the optical film 32 is a brightness enhancement film such as a reflective polarizer.

The cover lens 17 covers for example the displaying layer 14, and in particular its front surface, in order to protect it.

The cover lens 17 is for example made of plastic, such as PMMA or PC (polycarbonate) co-extrusion, or of a glass component.

An exemplar use of a digital display screen 10 as described above will now be described.

In operation, the display control unit 20 controls the generation of the image displayed by the image-displaying element 18.

The lighting control unit 22 controls individually the lighting sources 26 and in particular, dims the lighting intensity generated by each of the lighting zones 26, for example according to the image displayed on the image-displaying element 18.

In the first zone 24-1, the lighting sources 26 backlight directly the corresponding area of the image-displaying element 18.

Thanks to the optical function of the light-guide layer 26, the light generated by the lighting sources 26 in the first zone 24-1 is distributed to the second zone(s) 24-2. The light transmitted can thus backlights the corresponding area of the image-displaying element 18, i.e. facing the second zone 24-2.

The digital display screen 10 is particularly advantageous and in particular, allows reducing the number of lighting sources 26 needed, and thus reducing the cost and saving energy.

Indeed, in this digital display screen 10, only the first zone 24-1 of the backlighting device 16 comprises lighting sources 28, the first zone 24-1 corresponding for example to zone requiring local dimming.

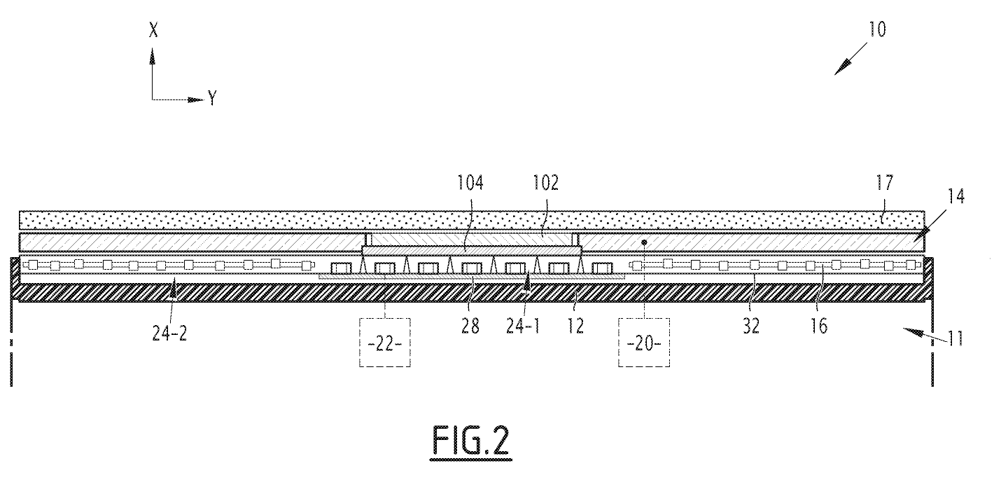

FIG. 2 shows a second embodiment of the invention.

This second embodiment differs from the first embodiment in that a part of the first zone 24-1 does not face the image displaying element 18.

In this second embodiment, the displaying layer 14 comprises for example a decorative layer 102 facing the first zone 24-1 of the backlighting device 24, and in particular the part of the first zone 24-1 that does not face the image displaying element 18.

In one example, the decorative layer 102 is a semi-transparent print, in particular which has both a decorative appearance and the semi-transparent light transmission.

In a preferred manner, the displaying layer 14 comprises a diffusing layer 104 arranged between the decorative layer 102 and the first zone 24-1 of the backlighting device 14.

The diffusing layer 104 has preferably the function of increasing the homogeneity of the light output.

In a particular embodiment, the image displaying element 18 surrounds the superimposition of the diffusing layer 104 and the decorative layer 102, thus forming the displaying layer 14.

1. A digital display screen comprising:
a back cover layer,
a displaying layer comprising an image displaying element, and
a backlighting device configured to backlight said displaying layer, the backlighting device being arranged between the back cover layer and the displaying layer according to a main direction, the backlighting device comprising a light-guiding layer defining a first zone and at least one second zone according to a second direction perpendicular to the main direction,
the backlighting device comprising a plurality of lighting sources arranged inside the first zone of the light-guiding layer,
the backlighting device comprising at least one optical film arranged inside each of the at least one second zone of the light-guiding layer.

2. Digital display screen according to claim 1, wherein the light-guiding layer defines two second zones, the first zone being arranged between the two second zones according to the second direction.

3. Digital display screen according to claim 1, comprising a cover lens covering the displaying layer.

4. Digital display screen according to claim 1, wherein the image displaying element is a thin-film-transistor liquid-crystal display.

5. Digital display screen according to claim 1, wherein the displaying layer comprises a decorative layer facing the first zone of the backlighting device.

6. Digital display screen according to claim 5, wherein the displaying layer comprises a diffusing layer arranged between the decorative layer and the first zone of the backlighting device.

7. Digital display screen according to claim 1, wherein the backlighting device comprises a plurality of barriers arranged inside the first zone of the light-guiding layer, each barrier being arranged longitudinally between each two of the plurality of lighting sources.

8. Digital display screen according to claim 1, wherein each of the plurality of lighting sources is a light emitting diode.

9. Vehicle component comprising at least one digital display screen according to claim 1.
